(19) United States
(12) Patent Application Publication
(10) Pub. No.: US 2006/0175702 A1
(43) Pub. Date: Aug. 10, 2006

(54) Ball grid array package

(76) Inventor: Kazuo Ishibashi, Tokyo (JP)

Correspondence Address: SQUIRE, SANDERS & DEMPSEY L.L.P., 14TH FLOOR, 8000 TOWERS CRESCENT, TYSONS CORNER, VA, 22182, US

(21) Appl. No.: 11/050,450

(22) Filed: Feb. 4, 2005

(51) Int. Cl. H01L 23/48

(52) U.S. Cl. 257/738

(57) ABSTRACT

A circuit assembly comprising a first circuit board and a second circuit board and an electrical connection between the first board and the second board, wherein the electrical connection comprises an outer coating of a electrically conductive first material and two inner cores of a second material, the first material having a lower melting point than the second material and the two cores being arranged to form a stack in which one of the cores is located between the other of the cores and one of the circuit boards.

The present invention relates to a circuit comprising two or more packages or modules attached to a motherboard in which at least one connection between the packages or between a package and the motherboard is formed from stacked solder balls.

The twin pressures of miniaturisation and increasing numbers of electronic components per circuit boards have led to much advancement in the field of circuit board technology. For example, conventionally components were attached to circuit boards using what is known as “through-hole” technology, in which components have leads that pass through holes in the circuit board and are soldered on the opposite side of the circuit board to the component. However, for large-scale assembly of circuit boards through-hole technology has now been largely replaced by surface mount technology (SMT).

SMT consists of three basic stages. Firstly, solder paste is printed on the surface of the circuit board using a stencil that matches the pattern of the components to be placed on the board. The components are then placed on the board in the positions marked out by the paste. The paste is tacky enough to retain the components in their correct positions on the circuit board. When all the components have been placed in the correct place, the circuit board is passed into a reflow oven, which melts the solder and forms a joint or connection between the component and the circuit board.

In an alternative SMT process, adhesive is dispensed on the board. The components are placed on the adhesive and the adhesive is cured to hold the components in place. The board is then flipped over and passed over a solder wave that provides solder for the joints.

Once the components have been soldered into place, the board may be packaged. Packaging is a process whereby the components attached to the board are encapsulated in another material. Encapsulating the components helps to protect them against physical damage e.g. by protecting the components from atmospheric moisture. Ecapsulants can be liquid or molded. However, liquid encapsulants are generally preferred because the cost of molding equipment is high and the geometry of the board can make the process difficult.

The main advantages of SMT as opposed to through-hole technology are as follows.
1. Components can be mounted on both sides of the circuit board, which helps to reduce the size of the assembled board;
2. Multi-layer circuit boards have more design flexibility, resulting in a decrease in size of the boards;
3. SMT lends itself to automated assembly and therefore, when used for volume production, it can decrease the cost of producing individual circuit boards; and
4. Smaller components can be used, allowing increased circuit density.

SMT tends to be used for high volume, leading edge electronic products such as mobile telephones and computer boards.

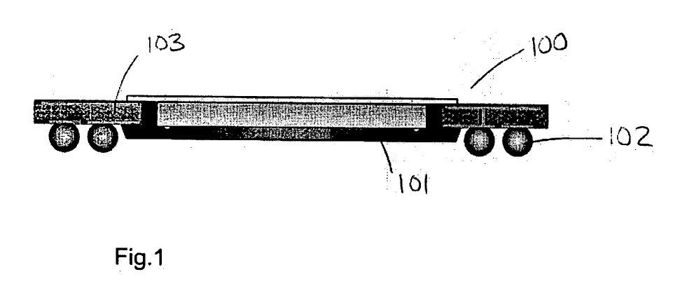

A ball grid array (BGA) is a chip package or module that has balls of solder attached to the underside of the package for mounting the package onto a motherboard. An example is illustrated in FIG. 1, which shows a BGA package generally at 100. The BGA package 100 comprises a component 101 mounted on a substrate 103. The BGA package has balls of solder 102 on its underside that can be used to mount the package on a motherboard or another package. A motherboard might typically be a conventional printed wired board (PWB). The solder joints form electrical and mechanical connections between the BGA and the motherboard.

BGAs typically have group of solder balls arranged in concentric rectangles. The BGA illustrated in FIG. 1 is called a single chip module (SCM) because it contains a single component. Multi-chip modules (MCM) containing more than one component are also available.

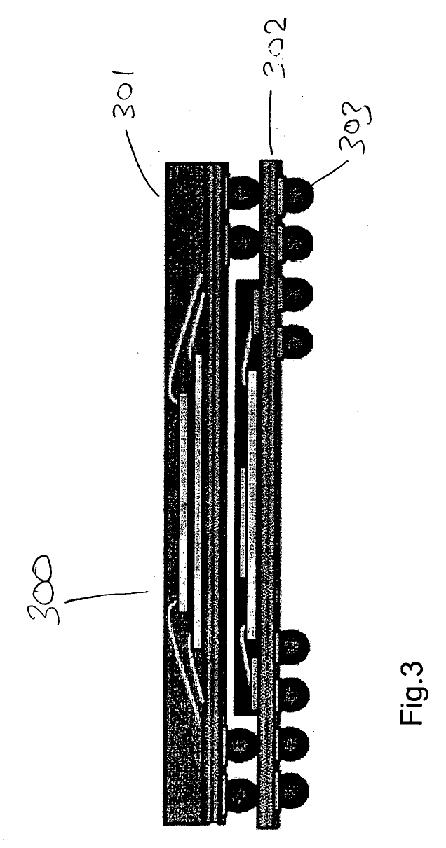

A BGA can be connected to a motherboard or another component using the SMT process described above. Many BGAs can be connected to a single motherboard, thus creating a single circuit board carrying a large number of components. BGAs can also be connected directly to both sides of the motherboard and may be stacked on top of each other (see e.g. FIG. 3).

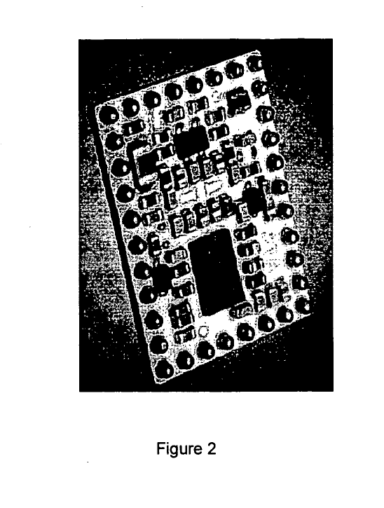

The BGA illustrated in FIG. 1 has what is known as a “cavity down” structure, in which the component and the solder balls for affixing the BGA to the motherboard are situated on the same side of the BGA. With this kind of structure, it is essential that there is sufficient clearance between the component, or the ecapsulant surrounding it, and the motherboard to avoid damaging the component. This is also true for double-sided BGAs, e.g. an engine module or a Bluetooth (RTM) module in which integrated circuits (ICs) and passives may be mounted on the same side of the module as the solder joints that are arranged on the periphery of the module substrate (see e.g. FIG. 2).

Obviously, the same consideration applies in applications where packages or modules are stacked on top of each other. In package stacking applications, the top package (usually combination memory) is solder mounted onto the top of a bottom package (usually an application specific integrated circuit or ASIC). Therefore, the mould cap or encapsulant of the bottom package (on the upper surface of the package substrate) should fit inside the peripherally arranged solder joints of the top package (on the lower surface of the package substrate). Therefore, it is essential to have sufficient height in the solder joints between the top and bottom packages.

It is important that solder height is sufficient and that it can be controlled. However, because the ball of solder makes a joint with the ball pad on the motherboard, some solder height is usually lost during assembly of a complete circuit board. Also, the solder ball collapses to some extent during reflow of the SMT process due to the weight of the package and warping of the package substrate.

One option to increase the height of the solder joint is to use larger solder joints. However, this approach is disadvantageous because increasing the size of the solder ball also increases the likelihood that neighbouring balls of solder will connect to form a joint bridge and thus a short circuit in the circuit board. To avoid the formation of joint bridges in this way, the ball pitch i.e. the distance between balls can be increased. However, increasing the ball pitch is not a preferred option because it increases the package size and therefore loses the miniaturisation benefits of using an SMT process.

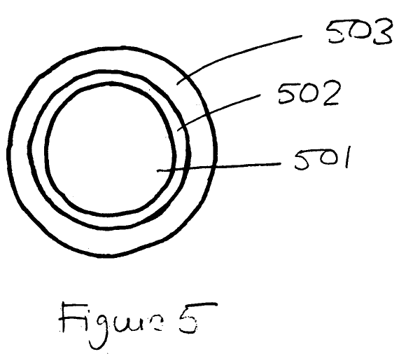

A different kind of solder ball that consists of a plastic or resin core surrounded by a layer of solder can be used. An example of such a solder-plated ball is illustrated in FIG. 5. The ball consists of a plastic base particle (501) surrounded by a conductive metal layer (502) and finally a plated solder layer (503). A ball such as that illustrated in FIG. 5 can be used in a conventional SMT process. As the conductive metal layer and the plastic or resin base particle have a higher melting point than the outer solder layer, they are largely unaffected by the reflow process that causes the outer solder layer to melt. Thus, the solder-plated ball is able to provide more accurate height spacing than a bulk solder ball, as the inner base particle does not collapse during reflow. The solder-plated ball also has a better board level reliability (BLR) than a conventional bulk solder ball as the base particle is able to absorb mechanical stress to a greater extent. However, although the risk of a joint bridge is lower than with the bulk solder ball, if a larger ball is used to increase joint height the risks of a joint bridge being formed during reflow still exist due to dimensional variations in ball size and ball pad solder mask registration. Also, the maximum ball height that can be achieved is limited by the ball pitch (ball spacing).

Therefore, there is a need to increase spacing between circuit boards in a controlled and accurate manner.

According to a first embodiment of the present invention, there is provided a circuit assembly comprising a first circuit board and a second circuit board and an electrical connection between the first board and the second board, wherein the electrical connection comprises an outer coating of a electrically conductive first material and two inner cores of a second material, the first material having a lower melting point than the second material and the two cores being arranged to form a stack in which one of the cores is located between the other of the cores and one of the circuit boards.

Preferably, each of the two inner cores is surrounded by a further electrically conductive layer. The further electrically conductive layer may be metallic.

The cores of the electrical connection may suitably be substantially spherical.

The first material may be solder and the second material may comprise a plastic or a resin.

According to a second embodiment of the present invention, there is provided a method for forming a circuit assembly comprising a first circuit board and a second circuit board, the method comprising forming an electrical connection between the first board and the second board from two connectors, each connector having an outer coating of a electrically conductive first material and an inner core of a second material and the first material having a lower melting point than the second material, the step of forming comprising arranging the two connectors to form a stack in which one of the cores is located between the other of the cores and one of the circuit boards.

The method may include the step of attaching one connector to each of the first and second circuit boards. The method may include the step of attaching the connectors to each other. The step of attaching one connector to each of the first and second circuit boards may be performed prior to the step of attaching the connectors to each other.

Preferably, the step of attaching one connector to each of the first and second circuit boards comprises heating the connector above the melting point of the first material such that the outer coating of the connector melts to form a connection with the circuit board, followed by cooling the connector below the melting point of the first material such that the connection between the connector and the circuit board solidifies.

Preferably, the step of attaching the connectors to each other comprises heating the connectors above the melting point of the first material such that the outer coatings of the two connectors melt to form a single coating surrounding the two inner cores, followed by cooling the connectors below the melting point of the first material such that the single coating solidifies.

For a better understanding of the present invention, reference is made to the following drawings in which:

FIG. 1 shows a “cavity-down” BGA;

FIG. 2 shows a Bluetooth module having solder-plated resin core balls as the inputs and outputs of the module;

FIG. 3 shows an example of package stacking using bulk solder balls;

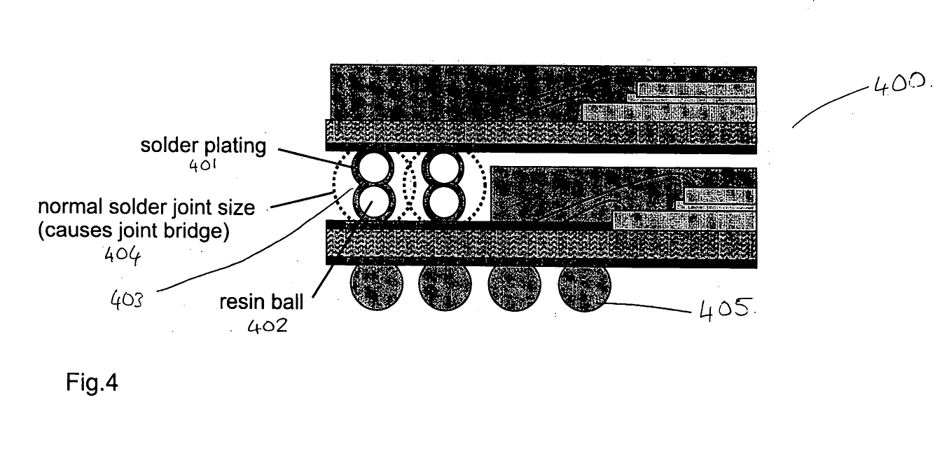

FIG. 4 shows an embodiment of the present invention in which two solder-plated resin balls are used to form a stack joint; and

FIG. 5 shows a solder-plated ball with a plastic base particle.

An embodiment of the present invention can be seen in FIG. 4. FIG. 4 illustrates two packages, shown generally at 400, joined by stacked solder joints 403 that each comprise two solder-plated resin balls 402. An increased solder joint height is achieved by mounting the two solder-plated balls on top of each other, without the risk of joint bridge that would arise if a single ball of the required height were used. For example, the dotted lines 404 in FIG. 4 illustrate how a joint bridge would be formed if single balls were used. Furthermore, the stacked arrangement of solder-plated balls in FIG. 4 achieves the required joint height without requiring an increased ball pitch and thus a loss of miniaturisation.

An increased joint height such as that illustrated in FIG. 4 would be difficult to realise using conventional bulk-solder balls. A stack of multiple bulk-solder balls would tend to melt and merge during reflow to form a single large solder ball.

A stacked solder joint such as that illustrated in FIG. 4 can be created using the following method. Firstly, solder-plated balls are attached to the upper surface of the package that will be the lower package in the stack. Solder-plated balls are similarly attached to the lower surface of the package that will be the upper package in the stack. The balls may be attached to their respective packages using a reflow process. This may involve initially attaching the balls to the packages using solder paste, adhesive or other suitable material. The upper package is then placed on top of the lower package so that the solder-plated balls on the lower surface of the upper package are positioned on top of the solder-plated balls on the upper surface on the lower package. Again, solder paste, adhesive or another suitable material may be used to keep the solder balls in the correct position. Finally, the whole stack is reflow processed so that the solder-plated balls form the necessary stacked joints.

Also shown in FIG. 4 is a conventional arrangement of single solder balls 405 on the lower surface of the lower package. These solder balls might be used to attach the lower package to a motherboard. Alternatively, the solder balls might be used to attach the lower package to a further package. The solder balls 405 might be solder-plated balls or conventional bulk solder balls e.g. where a stacked solder joint is not required.

The solder-plated balls may be mounted on a package or motherboard in advance or during construction of a complete circuit board.

FIG. 4 illustrates a stacked arrangement of two packages. However, this is for the purposes of example only. Multiple packages may be stacked on top of each other to complete a circuit. Similarly, FIG. 4 shows a stacking arrangement in which two solder-plated balls have been used to form a stacking joint. However, more than two solder-plated balls may be used to form a joint of a required height.

To produce the stacked joints correctly, the conventional reflow process should be optimised for forming stacked joints. For example, there is a risk that the upper ball in a stacked solder-plated ball joint may slip down from the upper ball during reflow. This risk can be reduced by using a thicker layer of solder to form the plating. Using thicker plating for the solder-plated balls creates an increased self-alignment effect between the two balls during reflow. Similarly, using a flux paste having increased tackiness so that the solder-plated balls are held in the correct position during the reflow process is advantageous. Other parameters that might beneficially be optimised for producing stacked joints include, for example, reflow temperature profile, air flow speed etc.

The solder balls illustrated in the figures are all shown to have a spherical shape. However, this is for the purposes of example only and is not intended to limit the scope of the present invention to any particular shape of solder ball.

Embodiments of the invention have been described herein with reference to solder-plated balls having resin or plastic cores. However, the stacked joint arrangement can be implemented using any appropriate materials to form the connector balls. For example, the invention could be implemented using solder-plated balls having a metal core. Suitable metals might include copper, high-melting point solder etc. Preferably, the inner core of the connector balls is made of a material having a higher melting point than that of the outer coating. Thus, while the outer coating softens during the reflow process, so as to become attached to a touching ball after cooling and solidifying, the inner core is preferably substantially unaffected by the reflow process so that the stacked joint does not collapse.

A solder-plated ball having a metal core might not be as effective for package to motherboard assembly as a solder-plated ball having a resin or plastic core because metal-core balls are not as good as absorbing mechanical stress. Underfilling (i.e. filling the spaces between the open spaces between the chip and the substrate or board with a non-conductive but mechanically protective material) may therefore be required if metal core balls are used. However, metal core balls could be used for “flip-chip” mounting a component or semiconductor device onto a silicon or low temperature so-fired ceramic (LTCC) substrate i.e. an electronic component or semiconductor device that is mounted directly onto a substrate, board or carrier in a “face-down” manner For example, a component could be mounted in a normal flip-chip manner on a substrate, followed by a second component mounted in a flip-chip manner using stacked solder balls (i.e. so that the stacked solder balls connect the second component to the substrate over the first component).

The present invention increases package design flexibility and is particularly useful for applications in which cavity-down packages are used. A particular advantage of the embodiments of the invention described herein is that only minimal modifications to existing package assembly processes are required.

The applicant hereby discloses in isolation each individual feature described herein and any combination of two or more such features, to the extent that such features or combinations are capable of being carried out based on the present specification as a whole in light of the common general knowledge of a person skilled in the art, irrespective of whether such features or combinations of features solve any problems disclosed herein, and without limitation to the scope of the claims. The applicant indicates that aspects of the present invention may consist of any such feature or combination of features. In view of the foregoing description it will be evident to a person skilled in the art that various modifications may be made within the scope of the invention.

1. A circuit assembly comprising a first circuit board and a second circuit board and an electrical connection between the first board and the second board, wherein the electrical connection comprises an outer coating of a electrically conductive first material and two inner cores of a second material, the first material having a lower melting point than the second material and the two cores being arranged to form a stack in which one of the cores is located between the other of the cores and one of the circuit boards.

2. A circuit assembly as claimed in claim 1, wherein each of the two inner cores is surrounded by a further electrically conductive layer.

3. A circuit assembly as claimed in claim 2, wherein the further electrically conductive layer is metallic.

4. A circuit assembly as claimed claim 1, wherein the cores of the electrical connection are substantially spherical.

5. A circuit assembly as claimed in claim 1, wherein the first material is solder.

6. A circuit assembly as claimed in claim 1, wherein the second material comprises a plastic or a resin.

7. A method for forming a circuit assembly comprising a first circuit board and a second circuit board, the method comprising forming an electrical connection between the first board and the second board from two connectors, each connector having an outer coating of a electrically conductive first material and an inner core of a second material and the first material having a lower melting point than the second material, the step of forming comprising arranging the two connectors to form a stack in which one of the cores is located between the other of the cores and one of the circuit boards.

8. A method as claimed in claim 7, comprising the step of attaching one connector to each of the first and second circuit boards.

9. A method as claimed in claim 7, comprising the step of attaching the connectors to each other.

10. A method as claimed in claim 9, wherein the step of attaching one connector to each of the first and second circuit boards is performed prior to the step of attaching the connectors to each other.

10. (canceled)

11. A method as claimed in claim 9, wherein the step of attaching the connectors to each other comprises heating the connectors above the melting point of the first material such that the outer coatings of the two connectors melt to form a single coating surrounding the two inner cores, followed by cooling the connectors below the melting point of the first material such that the single coating solidifies.

12. A method as claimed in claim 8, wherein the step of attaching one connector to each of the first and second circuit boards comprises heating the connector above the melting point of the first material such that the outer coating of the connector melts to form a connection with the circuit board, followed by cooling the connector below the melting point of the first material such that the connection between the connector and the circuit board solidifies.
